(19) United States
(12) Patent Application Publication
(10) Pub. No.: US 2018/0104758 A1
(43) Pub. Date: Apr. 19, 2018

(54) PREVENTING AN UNWANTED DEPOSITION OF METAL DURING a FLUX CLEAN

(71) Applicant: International Business Machines Corporation, Armonk, NY (US)

(72) Inventors: Charles L. Arvin, Poughkeepsie, NY (US); Thomas E. Lombardi, Poughkeepsie, NY (US)

(21) Appl. No.: 15/294,277

(22) Filed: Oct. 14, 2016

(51) Int. Cl. B23K 1/018; B23K 1/00; B23K 1/20; B23K 35/26; C23G 1/12; C23G 1/22; C23G 3/00; H01L 23/00; H01L 21/67

(52) U.S. Cl. CPC B23K 1/018; B23K 1/0016; B23K 1/203; B23K 35/262; C23G 1/12; B23K 2201/40; C23G 3/00; H01L 24/81; H01L 21/67034; H01L 21/6704; H01L 24/75; C23G 1/22

(57) ABSTRACT

A method includes applying flux solution during a soldering process. Metal ions are dissolved into the flux solution as a result of the soldering process. The method also includes rinsing the flux solution with a first rinse solution. The first rinse solution includes organic and/or sulfur species, and the organic and/or sulfur species stabilize the metal ions that are dissolved in the flux solution.

### BACKGROUND

The present invention relates in general to a method of preventing an unwanted deposition of metal onto a substrate. More specifically, the present invention relates to preventing an unwanted deposition of metal onto a substrate during a flux clean.

Soldering generally refers to a process where two or more points are electrically joined by connecting the two or more points with a melted filling material (i.e., the solder). When soldering metal connections of electrical devices, flux can be used in joining the metal connections. Specifically, in joining the metal connections, flux can be used to remove any metal oxide that is present on the surfaces of the metal connections, where the presence of metal oxide at the joined surfaces will adversely affect the joining of the metal connections. Further, flux can prevent oxidation at the metal connections, again facilitating the joining of the metal connections by the melted solder. The flux material is then subsequently cleaned/rinsed away.

### SUMMARY

According to one or more embodiments of the present invention, a method is provided. The method can include applying flux solution during a soldering process. Metal ions are dissolved into the flux solution as a result of the soldering process. The method can also include rinsing the flux solution with a first rinse solution. The first rinse solution includes organic and/or sulfur species, and these organic and/or sulfur species stabilize the metal ions that are dissolved in the flux solution.

According to one or more embodiments of the present invention, an apparatus is provided. The apparatus can include a receiving unit configured to receive a soldered device. The soldered device includes an electrical component soldered on a substrate. The soldered device further includes an applied flux solution during the soldering of the electrical component and the substrate, and metal ions are dissolved into the flux solution as a result of the soldering. The apparatus also includes a first rinsing unit configured to rinse the flux solution with a first rinse solution. The first rinse solution comprises organic and/or sulfur species, and the organic and/or sulfur species stabilize the metal ions that are dissolved in the flux solution.

### BRIEF DESCRIPTION OF THE DRAWINGS

The subject matter of the present invention is particularly pointed out and distinctly defined in the claims at the conclusion of the specification. The foregoing and other features and advantages are apparent from the following detailed description taken in conjunction with the accompanying drawings in which:

FIG. 1 depicts processes of performing first-level packaging, performing second-level packaging, and/or performing third-level packaging, in accordance with embodiments of the present invention;

FIG. 2 depicts an unwanted deposition of metal, in accordance with the previous approaches;

FIG. 3 depicts process steps of preventing an unwanted deposition of metal, in accordance with embodiments of the present invention; and

FIG. 4 depicts an apparatus for performing a method of embodiments of the present invention.

### DETAILED DESCRIPTION

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

As used herein, the term “about” modifying the quantity of an ingredient, component, or reactant of embodiments of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to,” such as, for example, “a first element selective to a second element,” means that the first element can be etched and the second element can act as an etch stop.

For the sake of brevity, conventional techniques related to electronic device and integrated circuit (IC) fabrication/assembly may or may not be described in detail herein. Moreover, the various tasks and process steps described herein can be incorporated into a more comprehensive procedure or process having additional steps or functionality not described in detail herein. In particular, various steps in the manufacture/assembly of electronic devices and semiconductor-based ICs are well known and so, in the interest of brevity, many conventional steps will only be mentioned briefly herein or will be omitted entirely without providing the well-known process details.

By way of background, however, a more general description of the assembly processes that can be utilized in implementing one or more embodiments of the present invention will now be provided. Although specific assembly/fabrication operations used in implementing one or more embodiments of the present invention can be individually known, the described combination of operations and/or resulting structures of the present invention are unique.

Embodiments of the present invention can enable metal ions to retain their stability during a flux cleaning operation, where the metal ions are dissolved within the flux material that is to be cleaned. By maintaining the stability of the ions, the ions do not come out of the flux during the flux cleaning operation, and thus the ions do not cause unwanted deposition upon a substrate, as described in more detail below.

“Peppering” generally refers to the unwanted deposition (or re-deposition) of dissolved metal ions upon a substrate. Specifically, during soldering operations, metal ions can become dissolved in the flux solution/material. With embodiments of the present invention, the soldering may occur between small gaps (that are located between the two points to be connected by soldering). For example, during soldering operations that use tin, tin (Sn) ions originating from the solder (and originating from the tin oxide on the surface of the solder) can become dissolved in the flux solution. Later, when the flux solution is to be washed/flushed/rinsed away, if the previous approaches of washing flux are used, these dissolved metal ions can come out of the flux solution. If metal ions are not either (1) flushed away quickly, (2) converted to an oxide while dissolved in the flux solution, (3) nor stabilized in some manner, the dissolved Sn metal ions can form unwanted bonds with the substrate surface (or with any other surface). The dissolved Sn metal ions will then chemically form tin oxide, which can lead to yield losses, and which can negatively affect device reliability.

In view of the above, embodiments of the present invention are directed to a method that prevents/avoids unwanted deposition/re-deposition onto surfaces, when performing either first-level, second-level, and/or third-level packaging, for example.

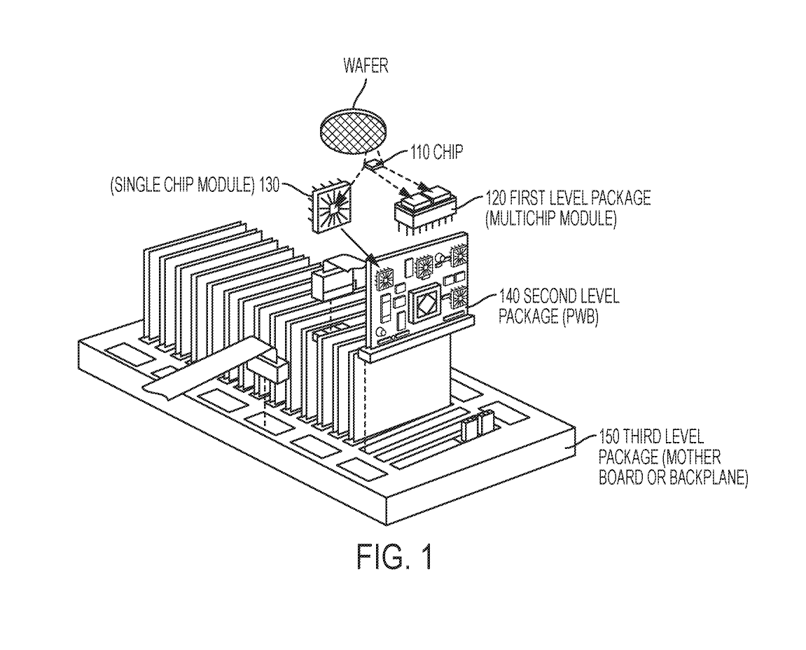

FIG. 1 depicts processes of performing first-level packaging, performing second-level packaging, and/or performing third-level packaging, in accordance with embodiments of the present invention. In the course of assembling electronic components, first-level packaging generally relates to a process of providing connections between an integrated circuit chip 110 and either a multichip module 120 or a single chip module 130. Second-level packaging generally relates to the process of providing connections between a chip module (120, 130) and a printed wiring board 140, for example. Third-level packaging generally relates to the process of providing connections between a printed wiring board 140 and a mother board 150 (or a backplane), for example. Embodiments of the present invention can be applicable to a soldering process of any of the first-level packaging, the second-level packaging, and/or the third-level packaging, for example.

When applying solder and flux during a packaging process, the flux typically removes stannous oxide from the solder (such as from a controlled collapse chip connection (C4) material, for example). Thus, the flux can facilitate the soldering process. Additionally, the flux also typically removes a small amount of the tin (Sn) from the solder. The Sn from the solder (and the Sn from tin oxide on the solder surface) dissolves within the solution of the flux. At the time that the flux is applied, and, at the time the Sn dissolves within the flux, an organic species within the flux acts to stabilize the dissolved Sn. Stabilizing the dissolved Sn generally relates to causing the dissolved Sn to not chemically react/bond with any other species, nor chemically react/bond with any surfaces.

With the previous approaches of rinsing/washing away the applied flux, when the washing process is applied to the flux (which now contains the dissolved Sn), the liquids of the washing process generally reduce the concentration of the flux's stabilizing species. As such, the previously stabilized dissolved Sn ions become destabilized, and the dissolved Sn is then able to react with surfaces (such as the solder mask and/or the substrate surface), which is an undesirable outcome. Upon reacting with the surfaces, the dissolved Sn causes a chemical bond. This unwanted chemical bond is a non-reversible reaction which, with exposure to oxygen, leads to formation of attached tin oxides/hydroxides.

Further, as discussed above, the soldering operations may occur in small-gap scenarios. The previous approaches of flushing away Sn ions with water typically occurred in scenarios with larger gaps. As such, with the larger gaps, the previous approaches could possibly rinse away the Sn ions with a fast-flow rush of rinsing water. However, because the small-gap scenarios do not allow for a large fast-flow rush of rinsing water, the Sn ions of the small-gap scenario cannot be readily washed away with just a rinsing of water. The small-gap scenarios can have different pitch sizes compared to the large-gap scenarios.

In view of the above, embodiments of the present invention can be utilized in small-gap scenarios. Embodiments of the present invention are directed to preventing the dissolved (stabilized) Sn ions from becoming destabilized, and thus embodiments of the present invention prevent the unwanted deposition of Sn ions upon surfaces. In contrast to the previous approaches, embodiments of the present invention perform a first rinsing with a pre-mixed solution, when performing a flux cleaning. This pre-mixed solution can include sulfate, methyl sulfonate, or sulfite-based salts. This pre-mixed solution can be an aqueous solution.

Embodiments of the present invention can maintain the stability of metal ions by performing the first rinsing with this aqueous solution of organic and/or sulfur species. By rinsing the flux (which contains the dissolved Sn ions), the dissolved Sn ions continue to be stable and do not leave the flux solution. Thus, with embodiments of the present invention, the flux (along with the Sn ions dissolved within) can be rinsed/washed/flushed away via the first rinsing. The Sn ions do not become destabilized, and thus will not result in subsequent attachment to the solder mask, nor to any other substrate surface, in accordance with embodiments of the present invention.

Next, embodiments of the present invention can perform a subsequent rinsing with, for example, water to remove any leftover organic and/or sulfur-based solution from the gap. For example, embodiments of the present invention can perform a rinse with deionized water to remove the sulfur-based solution from within the gap/cavity of the device.

In view of the above, with embodiments of the present invention, by performing the first rinsing with the pre-mixed solution, the dissolved Sn ions (that were dissolved within the flux) can be rinsed away, without causing the dissolved Sn ions to be de-stabilized and deposited on the substrate surface. The concentration of the pre-mixed salt solution can be around 0.001 M (mol/L) to 1.0 M. By using the above-described embodiments of the present invention, defects that are caused by tin peppering can be eliminated. Further, while the previous approaches attempt to eliminate the above-described defects by performing additional bakes and/or by using additional holding queue times, embodiments of the present invention can eliminate the above-described defects, without performing any additional bakes nor by using any additional holding queue times.

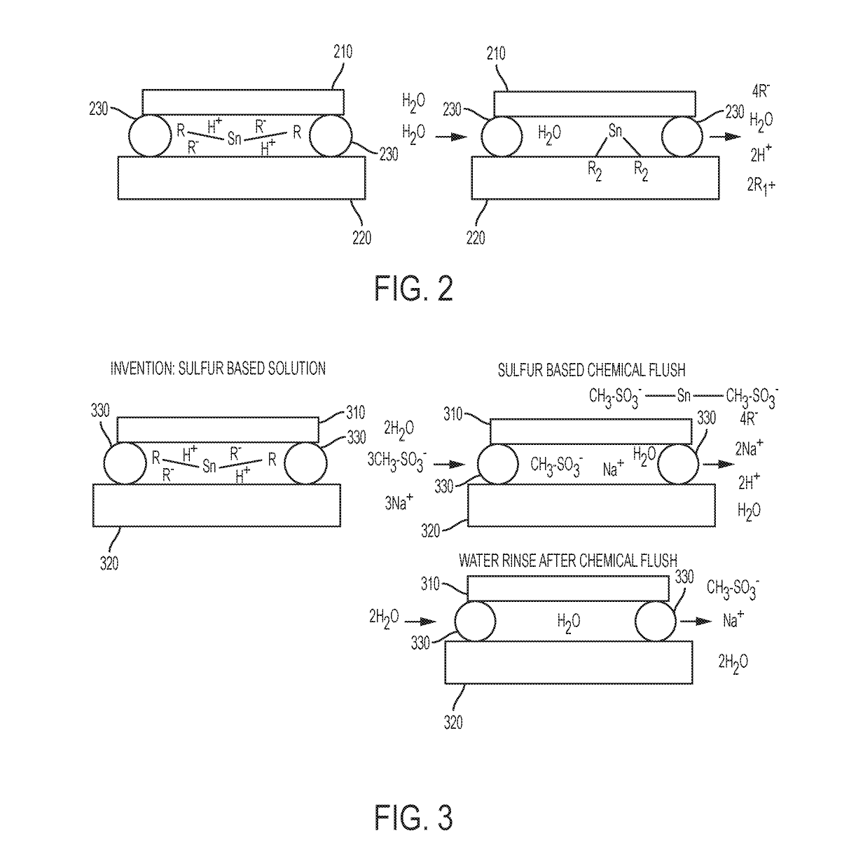

FIG. 2 depicts an unwanted deposition of metal, in accordance with the previous approaches. Referring to FIG. 2, a component 210 can be connected to substrate 220, using solder 230. Between the solder 230, a gap may exist where Sn ions are dissolved within a flux solution. The Sn can be bonded with organics (R) within the flux solution. In the example of FIG. 2, before the application of H₂O, a Sn²⁺ ion (cation name of “stannous ion”) is initially bonded with two organic ions named R¹⁻. Within the gap, hydronium ions (H+) can also exist because of the flux solution, as the flux solution can have a slightly acidic makeup. Organic species (R¹⁻) that are unassociated with the Sn can also exist in the gap as well. Next, with the previous approach of FIG. 2, water (H₂O) is used to rinse out the flux solution from the gap. As described above, the rinsing of water will cause the Sn ions to be destabilized, and thus the Sn will bond to yet other organics depicted as (R₂) of the surface of substrate 220. The rinsing of the previous approach of FIG. 2 will rinse out 4R¹⁻, H₂O, 2H¹⁺, and 2R¹⁺ from the gap.

Because the Sn has bonded to the organics of substrate 220, Sn will remain in the gap. The remaining Sn will have an undesirable effect upon device performance because the remaining Sn will interfere with underfill that is later added into the gap. Specifically, an underfill (which may include materials such as an epoxy, for example) can be filled into the gap between component 210 and substrate 220. This underfill will serve to alleviate device stress. However, any remaining Sn within the gap will negatively affect the underfill's ability to alleviate device stress by negatively affecting underfill adhesion, and thus device reliability is also negatively affected.

FIG. 3 depicts process steps of preventing an unwanted deposition of metal, in accordance with embodiments of the present invention. Referring to FIG. 3, a component 310 can be connected to substrate 320, using solder 330. Between the solder 330, a gap may exist where Sn ions are dissolved within the flux solution. With embodiments of the present invention, a first rinse is performed with an organic/sulfur-based chemical flush (i.e., a first rinse with methyl sulfonate (3CH₃—SO₃⁻)). As described above, the organic/sulfur-based first rinse will stabilize the Sn ions, and will rinse away the Sn ions, without having the Sn ions bond to the substrate 320. In the example of FIG. 3, the methyl sulfonate has reacted with the Sn, to form CH₃—SO₃—Sn—CH₃—SO₃. After the organic/sulfur-based first rinse, some of this organic/sulfur-based solution may be left within the gap between solder 330. Next, a de-ionized water rinse (i.e., 2H₂O) can be used to rinse out any of this organic/sulfur-based solution that is left within the gap.

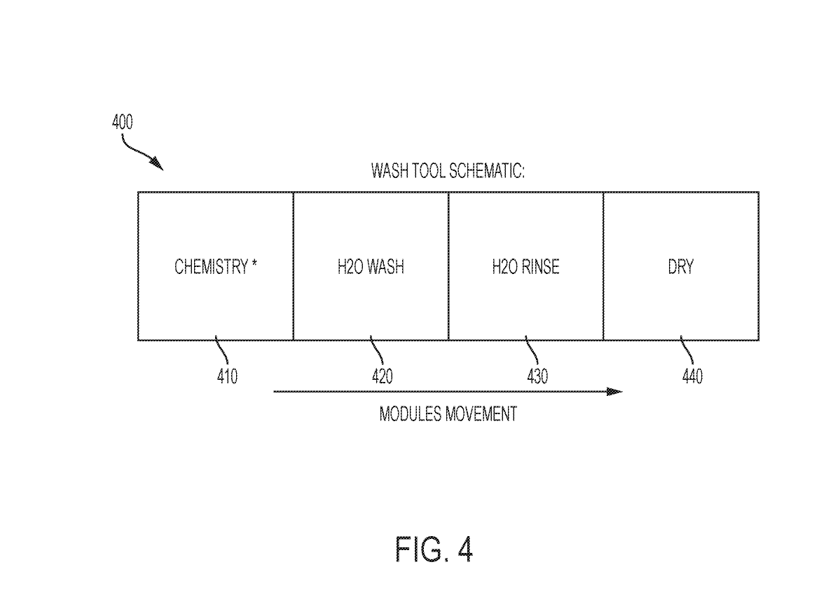

FIG. 4 depicts an apparatus for performing a method of embodiments of the present invention. Apparatus 400 can correspond to a wash tool that is used on electronics and semiconductor equipment, for example. Apparatus 400 can also correspond to process cleaning tools, for example. Apparatus 400 can include a chemistry section 410, an H₂O wash section 420, an H₂O rinse section 430, and/or a drying section 440. With embodiments of the present invention, chemistry section 410 can be configured to contain an amount of soluble sulfonate salt (such as, for example, Sodium Methyl Sulfonate). This amount soluble salt can be added into water that is used by H₂O wash section 420. The dissolved salt within the water can be the above-described first-rinse solution. Wash section 420 can then perform the first rinsing, which stabilizes the above-described metal ions. H₂O rinse section 430 can be configured to perform subsequent water rinsing to wash away any remaining sulfur solution of the first rinsing. Finally, a drying process can be performed by drying section 440.

In view of the above, embodiments of the present invention are directed to a solution that prevents/eliminates metal deposition onto surfaces during a flux cleaning. The previous approaches of removing unwanted metal deposition generally require additional thermal cycles and additional process steps. These additional cycles and steps generally increase the propensity of undesirable defects such as, for example, resin cracking.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments described herein.

What is claimed is:

1. A method for preventing unwanted deposition, the method comprising:
applying flux solution during a soldering process of a first-level packaging process, a second-level packaging process, or a third-level packaging process, wherein the soldering process connects a component to a substrate, a gap exists between the component and the substrate, metal ions are dissolved into the flux solution as a result of the soldering process, and the flux solution and the dissolved metal ions are present within the gap; and
rinsing the flux solution that is within the gap with a first rinse solution during the packaging process, wherein the first rinse solution comprises organic and/or sulfur species, and the organic and/or sulfur species stabilize the metal ions that are dissolved in the flux solution, and the rinsing the flux solution with the first rinse solution comprises rinsing with an aqueous solution.

2. The method of claim 1, wherein the rinsing the flux solution with the first rinse solution comprises rinsing with a sulfur species.

3. The method of claim 1, wherein the organic and/or sulfur species comprises at least one of sodium methylsulfonate, sodium sulfate, sodium sulfite and methyl sulfonic acid.

4. The method of claim 1, wherein the first rinse solution comprises a solution with a concentration between 0.001 M and 1.0 M.

5. (canceled)

6. The method of claim 1, wherein the dissolved metal ions comprise tin ions from solder of the soldering process.

7. The method of claim 1, further comprising:
rinsing, with a second rinse solution, to rinse away any organic and/or sulfur species left by the first rinsing.

8. The method of claim 1, wherein stabilizing the metal ions comprises preventing the metal ions from bonding to an unwanted surface.

9. The method of claim 8, wherein the unwanted surface comprises one of a substrate surface and a solder mask surface.

10. The method of claim 7, further comprising:
drying any leftover solution from the first rinse solution and the second rinse solution.

11. An apparatus of a wash tool, the apparatus comprises:
a receiving unit configured to receive a soldered device, wherein the soldered device comprises an electrical component soldered on a substrate, the soldered device further comprises an applied flux solution during the soldering of the electrical component and the substrate, and metal ions are dissolved into the flux solution as a result of the soldering; and
a first rinsing unit configured to rinse the flux solution with a first rinse solution, wherein the first rinse solution comprises organic and/or sulfur species, and the organic and/or sulfur species stabilize the metal ions that are dissolved in the flux solution.

12. The apparatus of claim 11, wherein the rinsing the flux solution with the first rinse solution comprises rinsing with a sulfur species.

13. The apparatus of claim 11, wherein the organic and/or sulfur species comprises at least one of sodium methylsulfonate, sodium sulfate, sodium sulfite and methyl sulfonic acid.

14. The apparatus of claim 11, wherein the first rinse solution comprises a solution with a concentration between 0.001 M and 1.0 M.

15. The apparatus of claim 11, wherein the rinsing the flux solution with the first rinse solution comprises rinsing with an aqueous solution.

16. The apparatus of claim 11, wherein the dissolved metal ions comprise tin ions from solder of a soldering process.

17. The apparatus of claim 11, further comprising:
a second rinsing unit configured to rinse away, with a second rinse solution, any organic and/or sulfur species left by the first rinsing.

18. The apparatus of claim 11, wherein stabilizing the metal ions comprises preventing the metal ions from bonding to an unwanted surface.

19. The apparatus of claim 18, wherein the unwanted surface comprises at least one of a substrate surface and a solder mask surface.

20. The apparatus of claim 17, further comprising:
a drying unit that dries any leftover solution from the first rinse solution or the second rinse solution.
